(19) United States
(12) Patent Application Publication
(10) Pub. No.: US 2008/0185700 A1
(43) Pub. Date: Aug. 7, 2008

(54) Adhesive Film and Method for Manufacturing Semiconductor Device Using Same

(75) Inventors: Nobuhiro Takamatsu, Chiba (JP); Shin Aihara, Aichi (JP)

Correspondence Address: BUCHANAN, INGERSOLL & ROONEY PC, POST OFFICE BOX 1404, ALEXANDRIA, VA, 22313-1404, US

(73) Assignee: MITSUI CHEMICALS, INC., Tokyo (JP)

(21) Appl. No.: 11/579,381

(22) PCT Filed: Apr. 28, 2005
(86) PCT No.: PCT/JP05/08132

§ 371 Date: Nov. 2, 2006

(30) Foreign Application Priority Data
May 6, 2004 (JP) 2004-137111
May 6, 2004 (JP) 2004-137498

(51) Int. Cl. H01L 21/78; H01L 23/00; B32B 27/32

(52) U.S. Cl. 257/678; 438/464; 428/355 EN; 257/E21.599; 257/E23.001

(57) ABSTRACT

The invention provides an adhesive tape which acts as a dicing tape which is excellent in dicing property and pickup property in a dicing step, and as an adhesive tape which is excellent in connection reliability in a step of bonding a semiconductor device with a supporting member. The adhesive film comprises a layer in which an adhesive layer (A) comprising an olefin polymer and an adhesive layer (B) are directly laminated to each other, wherein the 180° peel strength between the layer (A) and the layer (B) is not more than 0.7 N/10 mm.

### TECHNICAL FIELD

The present invention relates to an adhesive film used in manufacturing a semiconductor device such as an IC, LSI or the like and a method of using the adhesive film.

### BACKGROUND ART

Semiconductor wafers, such as silicon, gallium arsenide and the like, are manufactured in large diameters and after the wafers are cut and divided into chips (dicing), then the next step of die attaching for mounting the IC chips onto a package lead frame (referred to also as a die bonding step) is carried out. At this time, the semiconductor wafer is conveyed to the next step of a die bonding step after completing each step of dicing, washing, drying, expanding and pickup while being pre-attached to an adhesive sheet. As adhesive sheets for use in such steps from a step of dicing the semiconductor wafer to a pickup step, it is required that the adhesive sheets having sufficient adhesion to the wafer chips during the period from a dicing step to a drying step, but also having adhesion to such an extent that the adhesive does not attach to the wafer chip at the time of pickup. An IC chip picked up in the die attaching step is fixed to an IC chip mounting part (a mounting part) of a lead frame via an adhesive for attaching IC chips, which is applied onto the mounting part, such as an epoxy adhesive, a polyimide adhesive, silver paste or the like supplied in the form of a viscous liquid, thereafter, a semiconductor device is manufactured through a wire bonding step and a resin molding step. However, there have been problems in that, when the IC chip is extremely small, it is difficult to uniformly apply an appropriate amount of adhesive onto the IC chip, resulting in the adhesive being pushed out of the IC chip, or when the IC chip is large, it is difficult to adhere with enough adhesion due to deficient adhesive and the like. In the meantime, there has been proposed a film form adhesive for attaching an IC chip to a lead frame using a polyimide resin which is excellent in heat resistance. Furthermore, there has been proposed a dicing tape commonly used as a dicing tape and for die attaching (hereinafter referred to as a dicing tape with die attach film) in which an adhesive for attaching the IC chip is laminated onto a substrate film in such a way that it can be peeled off. Such an integrated tape has many advantages in terms of usability as well. Furthermore, in recent years, capacity of semiconductor devices, especially CPUs or memories is increasing, and, as a result, the semiconductor devices have been growing in size. Further, thickness of memories used in products such as IC cards or memory cards has been reducing. Along with increasing size and reducing thickness of the semiconductor devices, an adhesive tape that can avoid problems in use is required. The dicing tape with die attach film is also promising in this point. This kind of dicing tape commonly used as a dicing tape and for die attaching is disclosed in JP2003-197651A, JP 1996-53655A, JP1997-100450A, JP 1996-239636A, JP1998-335271A and the like. However, these dicing tapes with die attach film fail to fully satisfy the requirement to have sufficient adhesion to the wafer chip during dicing, and be easily peeled off at the time of pickup.

A method of attaching a back surface of a wafer has been paid attention as a method capable of suppressing the assembly cost to a relatively low level among the assembly methods using a film adhesive, since a semiconductor device applied with an adhesive is bonded to a supporting member and a device for dicing an adhesive film is not required, thus conventional assembling apparatus for silver paste can be used as is or with modification in a part of the apparatus such as addition of a heat platen or the like. In this wafer back surface attaching method, the semiconductor device is diced into chips by carrying out a dicing step after attaching a dicing tape to the film adhesive side. At that time, the dicing tape to be used is required to have enough adhesion lest each device be scattered due to rotation caused by a dicing saw during cutting. On the other hand, at the time of picking up, in order to prevent adhesive from attaching to each device or to prevent the device from being damaged, it also needs to satisfy a contradictory performance of low adhesion so that the device can be picked up. For this reason, a UV type dicing tape using an acrylic photo-curing resin for an adhesive has currently predominantly been used, and after dicing, the adhesive is photo-cured by UV irradiation to weaken the adhesion to enable picking up at the time of picking up. However, the UV type dicing tape has a problem in that it becomes defective by irradiation of sunlight during shipping or storage. Furthermore, in the case of UV type die attach film functioning as a dicing tape, films react with each other when irradiated with UV, therefore adhesion is increased to the contrary, and problems such as difficulty in picking up have occurred.

Since UV type dicing tape and highly reactive materials are used for these tapes, when attaching to a wafer at a high temperature of 100° C. or more is required, there are also problems other than the above problems, such as restriction on the type of dicing tape due to the requirement for heat resistance.

A pressure sensitive adhesive tape using non-reactive materials is disclosed in Japanese Patent No. 3280876 and JP1997-263734A. However, an acrylic adhesive is used for an adhesive, and therefore a special kind of peeling agent is used to deal with the problem. Furthermore, there is also a problem in that attachment at a high temperature of 100° C. or more is required for attaching a wafer.

[Patent Document 1] JP2003-197651A

[Patent Document 2] JP1996-53655A

[Patent Document 3] JP1997-100450A

[Patent Document 4] JP1996-239636A

[Patent Document 5] JP1998-335271A

[Patent Document 6] Japanese Patent No. 3280876

[Patent Document 7] JP1997-263734A

### DISCLOSURE OF THE INVENTION

### Problems Addressed by the Invention

Under these circumstances, an object of the present invention is to provide an adhesive tape for use both as a dicing tape and a die attach film comprising a die attach tape which has sufficient adhesion to a wafer chip in a step of dicing, an adhesion capable of being easily peeled off at a time of picking up, and serves as a die attach tape which has excellent connection reliability in a step of bonding a semiconductor device to a supporting member.

### Means of solving the problems

The present inventors have conducted extensive studies and, as a result, have found that the above object could be solved by controlling the adhesive strength between an adhesive layer (B), functioning as a die attach film, and an adhesive layer (A), functioning as a dicing tape. Thus, the present invention has been completed.

Specifically,

a first invention is an adhesive film comprising a layer in which an adhesive layer (A) comprising an olefin polymer and an adhesive layer (B) are adjacently laminated to each other, wherein the 180° peel strength between the layer (A) and the layer (B) is 0.7 N/10 mm or less.

The layer (A) comprising an olefin polymer and the layer (B) comprising a polyimide resin is a preferred embodiment from the viewpoint of having enough heat resistance to endure reflow soldering at a temperature of 260° C. or more.

The glass transition temperature (Tg) of the layer (B) being 50° C. or less is a preferred embodiment from the viewpoint of being capable of being laminated and attached onto the wafer at a low temperature of 100° C. or less.

The layer (A) comprising one, or two or more kinds of copolymer including at least two kinds of α-olefin selected from α-olefins having 2 to 12 carbon atoms as the major unit components is a preferred embodiment from the viewpoint that little change occurs in adhesion to the layer (B) around the time of heat treatment when attaching, or in long-term storage, or during shipping, and performance or quality of the layer (B) is not adversely affected.

The layer (B) further comprising a thermosetting resin is a preferred embodiment from the viewpoint of having high adhesion.

The layer (B) comprising a filler of 0 to 70 volume % is a preferred embodiment from the viewpoint of reinforcing effect of a thermoplastic resin and a thermosetting resin.

The layer (B) being laminated onto a part of the surface of the layer (A) is a preferred embodiment from the viewpoint that a cutting step for the layer (B) after an attaching step is unnecessary and an apparatus for attaching can be simplified.

A second invention is a method of manufacturing a semiconductor device characterized in that the method comprises: a step of cutting a semiconductor wafer into chips after laminating the adhesive film onto the semiconductor wafer via the layer (B); a step of peeling off the layer (A) from the layer (B); and a step of attaching the chips attached with the layer (B) to a substrate having circuits thereon or a film having circuits thereon via the layer (B).

The temperature for laminating the layer (B) onto the semiconductor wafer being 100° C. or less is a preferred embodiment from the viewpoint of handling.

A third invention is a semiconductor device manufactured by the foregoing method.

### EFFECT OF THE INVENTION

The adhesive film of the present invention has sufficient adhesion to the wafer chip during the period of from a dicing step to a drying step, and is capable of having an adhesion to such an extent that an adhesive does not attach at the time of picking up.

Furthermore, the adhesive film of the present invention can be attached to the wafer at low temperature, and has a function as a dicing sheet which is superior in anti-chipping properties and anti-cracking properties as a dicing film at the time of dicing, and can be used as an adhesive at the time of die mounting. Additionally, the adhesive film serves as a die attach film which is superior in uniformity in thickness, adhesive strength and shear strength properties, and endures severe moist heat conditions. Further, the semiconductor device manufactured from the adhesive film of the present invention has impact resistance and heat resistance which are equal, or superior, to that of conventional liquid epoxy type die-attach materials.

### BRIEF DESCRIPTION OF THE DRAWINGS

FIG. 1 A lamination of a die attach film part and a release film.

FIG. 2 A lamination in which a die attach film part has been punched out.

FIG. 3 A lamination of a dicing film part and a substrate layer.

FIG. 4 A cross-sectional view of the adhesive film of the present invention.

FIG. 5 A top view of the adhesive film of the present invention.

The meaning of the symbols in the drawings is as follows: 1, release film; 2, adhesive layer (B); 3, adhesive layer (B) after being cut by punching; 4, adhesive layer (A); 5, substrate layer.

### BEST MODE FOR CARRYING OUT THE INVENTION

The adhesive film and a method of manufacturing the adhesive film of the present invention will now be described in more detail.

Firstly, the adhesive layer (B) functioning as a die attach film will be explained. It is preferable that a resin composition of the adhesive layer (B) used in the present invention comprises a polyimide resin as a resin having an imide ring. Polyimides obtained from the diamines represented by the following general formulae (1), (2), (3) and (4) are particularly preferable from the viewpoint of having a low temperature adhesion.

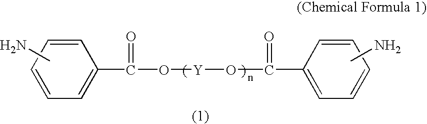

In the formula (1), n is an integer of from 1 to 50; Y represents an alkylene group having 2 to 10 carbon atoms; and a plurality of Y may be the same or different when n is 2 or more.

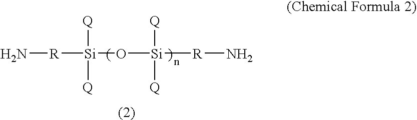

In the formula (2), R independently represents an alkylene group having 1 to 10 carbon atoms or a phenylene group; Q independently represents an alkyl group having 1 to 10 carbon atoms or a phenyl group; and n is an integer of from 1 to 50.

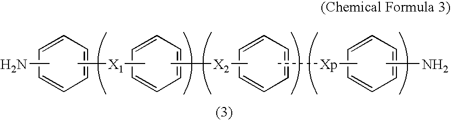

In the formula (3), p represents an integer of from 1 to 6; X₁ to Xₚ independently represent a bivalent group selected from the following structures.

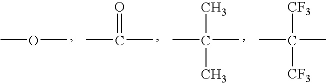

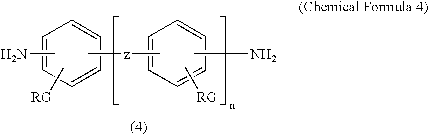

In the formula (4), wherein Z is a bivalent organic group which is independent from each other and represents a group selected from a group consisting of a single bond, —CO—, —SO₂—, —O—, —(CH₂)ₘ—, —NHCO—, —C(CH₃)₂—, —C(CF₃)₂— and —CO—O—; n and m each independently represent an integer of 0 or more and 5 or less; and RG each independently represent at least one kind of functional group selected from a group consisting of —OH, —COOH, —OCN and —CN.

The polyimide used for the adhesive layer (B) of the present invention preferably contains the diamine represented by the general formula (1) by 10 mole % or more and less than 100 mole %, more preferably 40 mole % or more and less than 100 moles %, in the whole diamine component, and the diamine represented by the foregoing general formulae (2) and/or (3) and/or (4) by 0 mole % or more and less than 90 mole %, more preferably 0 mole % or more and less than 40 mole %, in the whole diamine component.

Alternatively, it is preferable that the content of the diamine represented by the general formula (2) in the whole diamine component is 50 or more mole % and less than 100 mole %, preferably 60 mole % or more and less than 100 mole %, and the content of the diamine represented by the foregoing general formula (3) in the whole diamine component is 0 mole % or more and less than 50 mole %, preferably 0 mole % or more and less than 40 mole %. Furthermore, the adhesive layer (B) preferably contains a thermoplastic polyimide obtained by reacting the diamine components with a tetracarboxylic acid dianhydride, and a thermosetting resin. By using such diamine component compositions, the glass transition temperature (Tg) can be controlled to 50° C. or less and attachment at a low temperature of 100° C. or less can be conducted.

Among the diamine components represented by the general formula (1), a diamine having a p-amino benzoic ester group at both ends is preferable. Examples of a polyether oligomer include, though not restricted to, polytetramethyleneoxide-di-p-aminobenzoate, polytrimethyleneoxide-di-p-aminobenzoate and the like.

Examples of diaminopolysiloxanes represented by the general formula (2) include, though not restricted to, 1,3-bis(3-aminopropyl)tetramethylsiloxane, α,ω-bis(3-aminopropyl)polydimethylsiloxane, α,ω-bis(2-aminoethyl)polydimethylsiloxane, α,ω-bis(2-aminopropyl)polydimethylsiloxane, α,ω-bis(4-aminobutyl)polydimethylsiloxane, α,ω-bis(4-aminophenyl)polydimethylsiloxane, α,ω-bis(3-aminopropyl)polydiphenylsiloxane or the like. Among these, one with n of from 1 to 9 in the general formula (2) improves cohesion, and one with n of from 10 to 50 improves flexibility, which can be selected according to the foregoing purposes. However, using both are more preferable.

As the diamine represented by the general formula (3), any diamine having a structure with amino groups being bonded at any of o-, m- or p-position at both ends can be used, but the diamine with amino groups being bonded at the m-position is preferable.

Concrete examples of the general formula (3) include, though not restricted to, 3,3′-diaminobenzophenone, 4,4′-di aminobenzophenone, 3,3′-diaminodiphenylether, 4,4′-diaminodiphenylether, 1,3-bis(3-aminophenoxy)benzene, 1,4-bis(4-aminophenoxy)benzene, bis(3-(3-aminophenoxy)phenyl)ether, bis(4-(4-aminophenoxy)phenyl)ether, 1,3-bis(3-(3-aminophenoxy)phenoxy)benzene, 1,4-bis(4-(4-aminophenoxy)phenoxy)benzene, bis(3-(3-(3-aminophenoxy)phenoxy)phenyl)ether, bis(4-(4-(4-aminophenoxy)phenoxy)phenyl)ether, 1,3-bis(3-(3-(3-aminophenoxy)phenoxy)phenoxy)benzene, 1,4-bis(4-(4-(4-aminophenoxy)phenoxy)phenoxy)benzene, 4,4′-bis(3-aminophenoxy)biphenyl, 4,4′-bis(4-aminophenoxy)biphenyl, 2,2-bis[4-(3-aminophenoxy)phenyl]propane, 2,2-bis[4-(4-aminophenoxy)phenyl]propane, 2,2-bis[4-(3-aminophenoxy)phenyl]-1,1,1,3,3,3-hexafluoropropane, 2,2-bis[4-(4-aminophenoxy)phenyl]-1,1,1,3,3,3-hexafluoropropane and the like. 1,3-bis(3-(3-aminophenoxy)phenoxy)benzene and 4,4′-bis(3-aminophenoxy)biphenyl are preferable.

Examples of diamines represented by the general formula (4) include, though not restricted to, 3,3′-dihydroxy-4,4′-diaminobiphenyl, 4,4′-dihydroxy-3,3′-diaminobiphenyl, 3,3′-dicyano-4,4′-diaminobiphenyl, 4,4′-dicyano-,3,3′-diaminobiphenyl, 3,3′-dicarboxy-4,4′-diaminobiphenyl, 4,4′-dicarboxy-3,3′-diaminobiphenyl, 3,3′-dihydroxy-4,4′-diaminobenzophenone, 4,4′-dihydroxy-3,3′-diaminobenzophenone, 3,3′-dicyano-4,4′-diaminobenzophenone, 4,4′-dicyano-3,3′-diaminobenzophenone, 3,3′-dicarboxy-4,4′-diaminobenzophenone, 4,4′-dicarboxy-3,3′-diaminobenzophenone, 3,3′-dihydroxy-4,4′-diaminodiphenylether, 4,4′-dihydroxy-3,3′-diaminodiphenylether, 3,3′-dicyano-4,4′-diaminodiphenylether, 4,4′-dicyano-3,3′-diaminodiphenylether, 3,3′-dicarboxy-4,4′-diaminodiphenylether, 4,4′-dicarboxy-3,3′-diaminodiphenylether and the like. Among these, 3,3′-dihydroxy-4,4′-diaminobiphenyl is preferable.

The tetracarboxylic acid dianhydride used in the present invention is not restricted, and conventionally known tetracarboxylic acid dianhydrides can be used.

The tetracarboxylic acid dianhydride has 1 to 4 aromatic rings. When it has 2 or more aromatic rings, an aromatic tetracarboxylic acid dianhydride having a structure of being bonded via a single bond or a single atom therebetween is preferable. Concrete examples thereof include, pyromellitic acid dianhydride, 3,3′,4,4′-benzophenone tetracarboxylic acid dianhydride, 3,3′,4,4′-biphenyl tetracarboxylic acid dianhydride, oxy-4,4′-diphthalic acid dianhydride, ethylene glycol bistrimellitic dianhydride, 2,2-bis(4-(3,4-dicarboxypheonxy)phenyl)propane dianhydride and the like. Ethylene glycol bistrimellitic dianhydride is preferable.

Examples of a method of preparing a polyimide include known methods and all methods capable of preparing the polyimide can be applied. Of these methods, it is preferable to carry out a reaction in an organic solvent. As a solvent which can be used in this reaction, there can be exemplified, for example, N,N-dimethylformamide, N,N-dimethylacetamide, N-methyl-2-pyrrolidone, 1,2-dimethoxyethane, tetrahydrofuran, 1,3-dioxane, 1,4-dioxane, dimethylsulfoxide, benzene, toluene, xylene, mesitylene, phenol, cresol and the like. These can be used singly or in combination of two or more kinds.

Meanwhile, the concentration of the reaction raw material in a solvent in this reaction is usually from 2 to 50 weight % and preferably from 5 to 40 weight %. The molar ratio of the reaction between the tetracarboxylic acid dianhydride and the diamine component (the tetracarboxylic acid dianhydride/the diamine component) is preferably in the range of 0.8 to 1.2. Within this range, heat resistance is not deteriorated.

The reaction temperature for the synthesis of a polyamide acid, i.e. a precursor of polyimide, is usually 60° C. or less, and preferably 10° C. or more and 50° C. or less. The reaction pressure is not particularly restricted and the reaction can be sufficiently carried out under atmospheric pressure. Furthermore, the time required for the reaction is different depending on the type of the reaction raw material, the type of the solvent and the reaction temperature. However, it is usually from 0.5 to 24 hours, which is enough for the reaction. According to the present invention, a polyimide having a repeating unit structure corresponding to a polyamide acid can be obtained by heating the thus-obtained polyamide acid at from 100 to 400° C. for imidization or by performing chemical imidization using an imidizing agent such as an acetic anhydride or the like.

Furthermore, by carrying out the reaction at from 130 to 250° C., generation of the polyamide acid and heat imidization reaction concurrently proceed and polyimide according to the present invention can be obtained. Namely, the diamine component and the tetracarboxylic acid dianhydride are subjected to suspension or dissolution in an organic solvent for carrying out the reaction under heating at a temperature of from 130 to 250° C. By carrying out generation of the polyamide acid and dehydration imidization concurrently, the polyimide according to the present invention can be obtained.

The molecular weight of the polyimide of the present invention is not particularly restricted and arbitrarily determined according to usage or processing method. For the polyimide of the present invention, for example, the value of logarithmic viscosity number measured at 35° C. after dissolving the polyimide in N-methyl-2-pyrrolidone at a concentration of 0.5 g/dl can be adjusted to any value of from 0.1 to 1.5 dl/g by controlling the ratio of diamine to the tetracarboxylic acid dianhydride to be used. In the present invention, an expression of polyimide includes a resin in which a precursor thereof, i.e. a polyamide acid, partly coexists, in addition to 100% imidized polyimide.

Further, the polyimide solution obtained by the above reaction may be used as is or the polyimide solution may be fed into a poor solvent for precipitating the polyimide.

The adhesive component used in the layer (B) of the present invention preferably contains a thermosetting adhesive component. The thermosetting reaction proceeds and a three dimensional net-like structure is formed by heating, and thereby the component can strongly be adhered to an adherend such as a metal lead frame and tape or an organic hard substrate.

Such thermosetting adhesive components are generally composed of a thermosetting resin such as an epoxy resin, a phenol resin, a urea resin, a melamine resin or the like, and a proper curing accelerator relative to each resin. A variety of the thermosetting adhesive components have been known. In the present invention, the thermosetting adhesive component is not particularly restricted and various known thermosetting adhesive components can be used. Examples of the adhesive component include a resin composition of an epoxy resin (I-1) and a heat-activated potential epoxy resin hardener (I-2).

The thermosetting resin is not particularly restricted as far as it forms a three dimensional net-like structure by heating. From the viewpoint of excellent hardenability, a resin comprising an epoxy resin containing at least two epoxy groups in a molecule and a hardener is preferable.

As for the epoxy resin, there can be exemplified, for example, glycidyl ethers of bisphenol A, bisphenol S and bisphenol F, phenol novolac type epoxy resins, biphenyl type epoxy compounds, and the like.

The blending amount of the epoxy resin is from 1 to 200 weight parts and preferably from 1 to 100 weight parts based on 100 weight parts of the polyimide. If the amount is within this range, heat resistance can be maintained and film-forming ability is not deteriorated.

Furthermore, as for the hardener, there can be exemplified, for example, an imidazole type hardener, a phenol type hardener, an amine type hardener, an acid anhydride type hardener and the like. The imidazole type hardener and the phenol type hardener are preferable, and the imidazole type hardener is particularly preferable. When the phenol type hardener is used, a xyloc type hardener represented by the following formula (5) or (6) is preferable. From the viewpoint of storage stability of the resin composition, a hardener having heat potential and a long pot life is preferable.

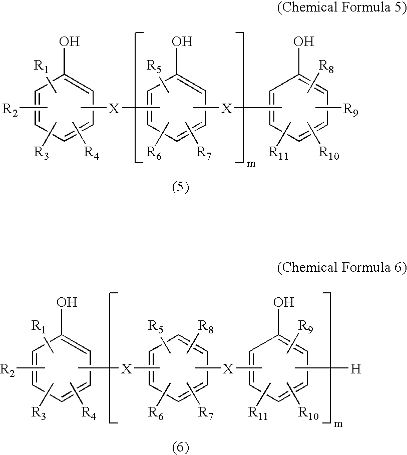

wherein R₁, to R₁₁ are each independently represent a hydrogen, an alkyl group having 1 to 10 carbon atoms, a phenyl group or a hydroxyl group; m is an integer of from 1 to 10; and X represents a bivalent organic group.

Examples of X include the following groups.

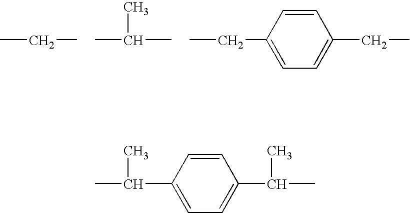

Examples of the xyloc type hardener include xylylene modified phenol novolac, p-cresol novolac and the like. A compound represented by the following general formula (7) is favorable.

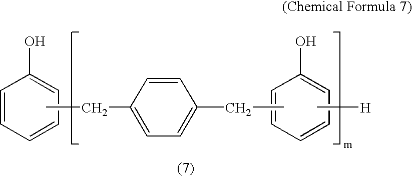

wherein m represents an integer of from 1 to 10.

The blending amount of the hardener is preferably in the range of 0 to 20 weight parts based on 100 weight parts of the epoxy resin. If the amount is within this range, it is difficult to create gel in the resin solution state and storage stability of the resin solution is excellent.

The adhesive layer (B) may contain a filler. The filler is not particularly restricted as far as it is a known filler. The filler is preferably contained in the amount of from 0 to 70 volume %. Concrete examples of an organic filler include a particle type filler which is highly polymerized or cross-linked until it becomes insoluble in a solvent dissolving a resin such as an epoxy resin, a melamine resin, a urea resin, a phenol resin and the like. Concrete examples of an inorganic filler include particles of a metal oxide such as alumina, antimony oxide, ferrite and the like; or particles of silicates such as talc, silica, mica, kaolin, zeolite and the like; and particles of barium sulfate, calcium carbonate and the like. The above filler can be used singly or in combination of two or more kinds.

Furthermore, a coupling agent may be added as needed. The coupling agent is not particularly restricted as far as the aim of the present invention is not impaired. The coupling agent preferably has a favorable solubility into the resin dissolved solvent. Concrete examples thereof include a silane coupling agent, a titanium coupling agent and the like.

In order to make the obtained resin composition the adhesive layer (B), firstly, apply the adhesive resin composition comprising the above components, in the form of varnish, onto the peeling sheet, according to generally known methods such as a comma coater, a die coater, a gravure coater or the like, then dry it to obtain the adhesive layer (B). In this manner, the adhesive layer (B) functioning as a die attach film can be prepared.

The thickness of the adhesive layer (B) of the present invention is preferably in the range of about 1 to 100 μm and more preferably in the range of about 5 to 30 μm.

Next, the adhesive layer (A) functioning as a dicing tape of the present invention will be explained. The adhesive layer (A) contains an olefin polymer. The adhesive layer (A) of the present invention is laminated adjacently onto the adhesive layer (B). The ratio of the 180° peel strength (PB) between the adhesive layer (B) and a semiconductor wafer to the 180° C. peel strength (PA) between the adhesive layer (A) and the adhesive layer (B), (PB/PA), is preferably 5 or more and more preferably 10 or more, when the adhesive film is laminated and attached onto a silicon wafer via the adhesive layer (B). The peel strength between the adhesive layer (A) and the adhesive layer (B) is preferably 0.7 N/10 mm or less, more preferably 0.5 N/10 mm or less, and still more preferably in the range of 0.1 N/10 mm or less. Furthermore, an adhesive tape in which the adhesive layer (A) and the adhesive layer (B) do not substantially cause a chemical reaction is preferable.

The peel strength between the adhesive layer (A) and the adhesive layer (B) can be controlled by regulating the adhesion of each layer. For the adhesive layer (A), as described later, adhesion can be controlled by regulating the content ratio of propylene, 1-butene and an α-olefin having 5 to 12 carbon atoms. Furthermore, adhesion of the adhesive layer (A) can also be controlled by adding a mixed resin comprising a cooligomer of an α-olefin other than the aforementioned α-olefins and ethylene. As for the adhesive layer (B), adhesion can be controlled by regulating the ratio of a monomer having a flexible molecular skeleton represented by the foregoing general formula (1) and a monomer having a stiff molecular skeleton represented by the general formula (2) at the time of polymerization of polyimide.

The meaning of not substantially causing a chemical reaction here is that the adhesive layer (A) does not chemically react with polyimide or the like in the adhesive layer (B) at the time of UV irradiation or the like. Further, primer layers may also be provided on the surfaces of the adhesive layers (A) and (B), which also falls within the scope of the present invention.

The major component of an adhesive of the adhesive layer (A), can be exemplified by, for example, an acrylic polymer, a polyolefin polymer and the like, but the olefin polymer is particularly preferable. However, the peel strength between the adhesive layer (A) and the adhesive layer (B) at the time of picking up is preferably 0.7 N/10 mm or less.

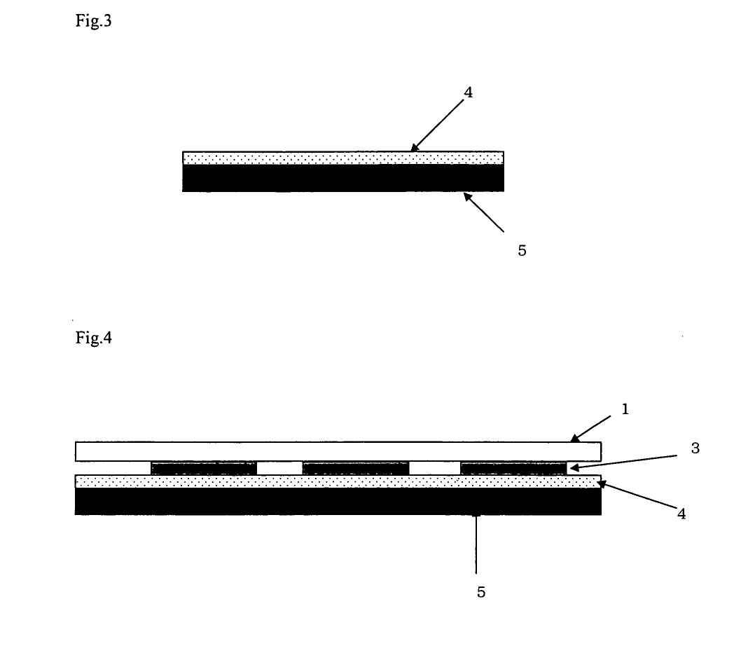

The adhesive layer (A) in the present invention is preferably laminated onto a substrate layer 5. The laminate (FIG. 3) has a function as a dicing tape. The adhesive layer (A) and the substrate layer 5 preferably have heat resistance of about 100° C. and sufficiently endure heating and pressing at the time of being laminated onto a semiconductor wafer.

The adhesive layer (A) is preferably an adhesive layer in which a chemical reaction such as a cross-linking reaction, a decomposition reaction or the like does not occur during an irradiation treatment with energy ray such as a UV irradiating treatment or a heating treatment, and substantially no reactive component is contained so that properties such as adhesion does not change around the time of the treatment. The adhesive layer (A) can be peeled off from the adhesive layer (B).

Furthermore, the adhesive layer (A) of the present invention is preferably an adhesive layer which does not contain a corrosive ion such as a sodium ion, a potassium ion, a chloride ion, a fluorine ion, a nitrite ion, a nitrate ion, a phosphate ion, or a sulfate ion, or a metallic ion such as an iron ion, a nickel ion, a copper ion, an aluminum ion, or a chromate ion. Further, the substrate layer 5 of the present invention preferably contains less amount of the reactive component than the adhesive layer (A), and also the level of the amount of the corrosive ion or the metallic ion is preferably lower than the adhesive layer (A).

A laminate comprising the adhesive layer (A) and the substrate layer 5 of the present invention preferably has an ion analysis value of less than 1 ppm by eliminating a reactive component such as a corrosive ion or a metallic ion from a step of manufacturing raw materials of the substrate layer or the adhesive layer, and a step of manufacturing an adhesive tape.

It is preferable that the substrate layer 5 and the adhesive layer (A) of the present invention are firmly integrated together with each other. For example, a laminate is scratched in a checkerboard pattern with a knife and then an adhesive tape is attached thereon. The interface between the adhesive layer (A) and the substrate layer 5 is observed when the adhesive tape is peeled away. In this checkboard scale peeling test, it is preferable to achieve a level such that the peeling does not occur on the whole surface, in terms of enhancing efficiency of converting an external expansive power applied to the laminate functioning as the above dicing tape into a peeling power.

The thickness of the adhesive layer (A) of the present invention is preferably in the range of about 1 to 50 μm and more preferably in the range of about 5 to 30 μm.

The adhesive layer (A) of the present invention is laminated on one side of the substrate layer 5 and preferably comprises an olefin polymer as the major component for the stability in the wafer processing, and particularly preferably comprises an olefin polymer which does not comprise a polar group.

Furthermore, it is preferable that the adhesive layer (A) of the present invention comprises an α-olefin copolymer having major unit components of at least two kinds of α-olefins selected from α-olefins having 2 to 12 carbon atoms as the major component, or two of more kinds of α-olefin copolymers may be blended therein. Further, the adhesive layer (A) preferably contains the above-described α-olefin copolymer, a thermoplastic elastomer and an ethylene/other α-olefin cooligomer, and the α-olefin copolymer forms a continuous phase while the thermoplastic elastomer forms a dispersed phase.

In the adhesive layer (A) of the present invention, it is preferable that the α-olefin copolymer preferably forms a continuous phase and the thermoplastic elastomer forms a dispersed phase, since it becomes possible to satisfy both softness for securing conformance to the irregularity of the wafer surface and Young's modulus E′ of the adhesive layer necessary for peeling off the chips.

Examples of the α-olefin having 2 to 12 carbon atoms, i.e., a raw material of the olefin polymer constituting the adhesive layer (A) of the present invention include, for example, ethylene, propylene, 1-butene, 1-pentene, 3-methyl-1-butene, 1-hexene, 4-methyl-1-pentene, 3-methyl-1-pentene, 1-heptene, 1-octene, 1-decene, 1-dodecene and the like. When a copolymer comprising at least two kinds of monomer selected from these α-olefins are used as the major component of the adhesive layer (A), the total content of α-olefin copolymers occupying in the adhesive layer (A) is usually preferably 30 weight % or more and more preferably 50 weight % or more.

An adhesive layer preferably comprises a copolymer obtained by copolymerizing three components of propylene, 1-butene and α-olefin having 5 to 12 carbon atoms, among these α-olefin copolymers. In particular, an adhesive layer containing a copolymer obtained by polymerizing a monomer composition comprising 10 to 85 mole % of propylene, 3 to 60 mole % of 1-butene and 10 to 85 mole % of α-olefin having 5 to 12 carbon atoms is preferable from the viewpoint of excellent adhesive properties of maintaining attachment to the adhesive layer (B) at a temperature range of around room temperature to a temperature for processing a wafer, namely, at a temperature range of about 20 to 80° C. Further, an adhesive layer containing a copolymer obtained by polymerizing a monomer composition comprising 15 to 70 mole % of propylene, 5 to 50 mole % of 1-butene and 15 to 70 mole % of α-olefin is preferable. As for the α-olefin having 5 to 12 carbon atoms, 4-methyl-1-pentene is preferable.

Meanwhile, when a copolymer obtained by copolymerizing the three components of propylene, 1-butene and α-olefin having 5 to 12 carbon atoms is contained in the adhesive layer (A), the content of the copolymer occupying in the adhesive layer is usually preferably 30 weight % or more, and more preferably 40 weight % or more.

Concrete examples of the above-described thermoplastic elastomer include polystyrene elastomers, polyolefin elastomers, polyamide elastomers, polyurethane elastomers, polyester elastomers and the like.

As for a preferred structure of the thermoplastic elastomer, a structural element of a block copolymer is represented by the general formula A-B-A or A-B, wherein A represents an aromatic vinyl polymer block or an olefin polymer block showing crystalline and B represents a diene polymer block or an olefin polymer block obtained by hydrogenating the diene polymer block.

Examples of the polystyrene elastomers include a block copolymer of a polystyrene block constituting a hard portion (crystal portion) and a diene monomer polymer block constituting a soft portion or a hydrogenated polymer thereof. Concrete examples thereof include styrene/isoprene/styrene block copolymer (SIS), styrene/butadiene/styrene block copolymer (SBS), styrene/ethylene/butylene/styrene block copolymer (SEBS), styrene/ethylene/propylene/styrene block copolymer (SEPS) and the like. These can be used singly or in combination of two or more kinds.

For example, the styrene/isoprene/styrene block copolymer comprises styrene polymer block of from about 12,000 to 100,000 in an average molecular weight and isoprene polymer block of from about 10,000 to 300,000 in an average molecular weight. The content ratio of the styrene polymer block to the isoprene polymer block in the SIS is usually (5 to 50)/(50 to 95) and preferably (10 to 30)/(70 to 90) by a weight ratio.

The styrene/ethylene/propylene/styrene block copolymer is obtained by hydrogenating the styrene/isoprene/styrene block copolymer.

Concrete examples of the SIS include a product available under the registered trade name JSR SIS from JSR Corporation, a product available under the registered trade name CLAYTONE D from Shell Chemicals Japan Ltd. and the like. Concrete examples of SEPS include a product available under the registered trade name SEPTONE from Kuraray Co., Ltd.

Examples of the aforementioned polyolefin elastomer include a block copolymer of a polyolefin block forming a polymer having high crystallinity such as polypropylene constituting a hard portion with a monomer copolymer block showing amorphousness constituting a soft portion. Concrete examples thereof include olefin (crystalline)/ethylene/butylene/olefin (crystalline) block copolymer, polypropylene/polyethyleneoxide/polypropylene block copolymer, polypropylene/polyolefin (amorphous)/polypropylene block copolymer and the like. Concrete examples thereof include a product available under the trade name DYNARON from JSR Corporation.

Concrete examples of the polyester elastomer include polybutyleneterephthalate/polyether/polybutyleneterephthalate block copolymer and the like.

As the components of the adhesive layer (A) of the present invention, when the thermoplastic elastomer is used, the content ratio of the thermoplastic elastomer occupying in the adhesive layer is usually preferably from 0 to 60 weight %, and more preferably from 5 to 40 weight %.

In order to improve the adhesive properties represented by adhesion of the adhesive layer (A) of the present invention, in addition to the α-olefin copolymer obtained by copolymerizing the above-described three components of α-olefin having 2 to 12 carbon atoms, other α-olefin copolymers can be contained in the adhesive layer. At this time, the total content of the copolymer comprising three components of the propylene, 1-butene and α-olefin having 5 to 12 carbon atoms to other α-olefin copolymers occupying in the adhesive layer is preferably at least 50 weight % or more.

As the other α-olefin copolymers, a copolymer comprising at least two kinds of α-olefins selected from ethylene, propylene, 1-butene and 1-hexene is preferable. Examples of the α-olefin copolymer include ethylene/propylene copolymer, ethylene/1-butene copolymer, ethylene/1-hexene copolymer, propylene/1-butene copolymer, propylene/1-hexene copolymer, 1-butene/1-hexene copolymer and the like. Concrete examples of the copolymer include a product available under the registered trade names of TAFMER A and TAFMER P from Mitsui Chemicals, Inc. and the like.

Meanwhile, the ethylene/other α-olefin cooligomer is a low-molecular ethylene/other α-olefin copolymer which is in a liquid state at room temperature. Examples of α-olefin include α-olefins having 3 to 20 carbon atoms such as propylene, 1-butene, 1-pentene, 1-hexene, 1-octene, 1-decene, 1-dodecene, 1-tetradecene, 1-hexadecene, 1-octadecene, 4-methyl-1-heptene and the like. Among these, an α-olefin having 3 to 14 carbon atoms is preferable.

The cooligomer usually has a number-average molecular weight in the range of 100 to 10,000 and preferably in the range of 200 to 5,000. Furthermore, the ethylene unit content in the cooligomer is usually preferably from 30 to 70 mole % and more preferably from 40 to 60 mole %.

When the cooligomer is used as a constituent component of the adhesive layer (A) of the present invention, the content ratio of the cooligomer occupying in the adhesive layer (A) is usually preferably from 0 to 20 weight % and more preferably from 0 to 10 weight %.

As the constituent component of the adhesive layer (A), in addition to the above-described α-olefin copolymer obtained by copolymerizing three components of α-olefin having 2 to 12 carbon atoms, using the above-described other α-olefin copolymer is favorable from the viewpoint that the glass transition temperature is lowered, the 180° peel strength, shear/peel strength and Young's Modulus E′ can be regulated in a suitable range, and low temperature adhesive properties can be improved.

Further, as the constituent component of the adhesive layer (A), using a mixed resin obtained by combining the above-described α-olefin copolymer with the ethylene/other α-olefin cooligomer is favorable from the viewpoint that the glass transition temperature is lowered, the 180° peel strength, shear/peel strength and Young's modulus E′ can be regulated in a suitable range, and the viscosity can be regulated in a suitable range.

Further, as the constituent component of the adhesive layer (A), using a mixed resin comprising the above-described α-olefin copolymer and the thermoplastic elastomer is favorable from the viewpoint that the glass transition temperature, shear/peel strength and Young's modulus E′ can be regulated in a suitable range, and the 180° peel adhesion required for over the temperature range of from room temperature (about 20° C.) to high temperature (about 80° C.) can be improved.

The adhesive layer (A) of the present invention may further contain various minor components, in addition to the α-olefin copolymer, the thermoplastic elastomer and the ethylene/other α-olefin cooligomer, to such an extent that the aim of the present invention is not hindered. For example, a plasticizer such as a liquid butyl rubber, a tackifier such as polyterpene and the like may be contained. In the present invention, among these minor components, it is preferable to select the kind and minimize the amount of the component having a functional group or an unsaturated bond which exhibits adhesiveness, to prevent change in adhesion with time after attachment (due to heating, pressurization, humidity, UV rays and the like) or causing an adverse effect to an adherend.

Further, the adhesive layer (A) of the present invention may contain various additives generally blended in such kind of adhesive layer material. For example, inorganic or organic polymer type fillers, pigments, UV absorbers, antioxidants, heat-resistant stabilizers, lubricants and the like may be contained.

The thickness of the adhesive layer (A) is preferably in the range of about 1 to 50 μm. When the thickness of the adhesive layer (A) is thicker, uniformity in adhesion is much superior. However, the thickness being more than 50 μm is not preferable since chipping or cracking might easily occur in dicing processing. Further, the thickness of the adhesive layer (A) being less than 1 μm is not preferable since uniformity in adhesion might become unstable.

The Young's modulus E′ of the substrate layer 5 of the present invention is preferably in the range of 100 to 1,000 MPa. When the Young's modulus E′ of the substrate layer 5 is less than 100 MPa, it is not preferable since peeling does not proceed even when expanded, and the peeling property becomes worse. According to the computation of the expanded peeling model of the present invention, substrate layer 5 with higher Young's modulus E′ has better peeling property. On the other hand, when the Young's modulus E′ of the substrate layer 5 exceeds 1,000 MPa, it is not preferable since it is difficult to expand in an ordinary apparatus.

The thickness of the substrate layer 5 is preferably in the range of about 50 to 500 μm. When the thickness of the substrate layer 5 is thicker, the peeling property is much superior. However, the thickness exceeding 500 μm is not preferable since the handling ability as a tape is worsened. Further, the thickness of the substrate layer 5 being less than 50 μm is not preferable since the substrate layer might be broken during cutting.

The substrate layer 5 comprises a single or two or more of thin layers, and constituent component thereof can be selected from any material such as a synthetic resin, a natural resin and the like without restriction, as far as the material has both stretchability and strength. From the viewpoint of the easiness of regulating the Young's modulus E′ of the substrate layer 5 in the range of 100 to 1,000 MPa and in respect of water resistance, heat resistance, electrolytic solution resistance, etching solution resistance, waste processability and the like, the substrate layer 5 preferably comprises a halogen-free synthetic resin as the major component. Concrete examples thereof include olefin polymers, polyamide, polyester, polyether, polycarbonate, polyurethane and the like.

It is particularly preferable that the substrate layer 5 of the present invention comprises an olefin polymer as the major component from the viewpoint that stability in the wafer processing is excellent, no toxic gas such as a halogen compound represented by dioxin and the like is generated at the time of incineration after use, and strong adhesion to the adhesive layer is easily formed.

Concrete examples of the olefin polymer include polyethylene polymers such as a low density polyethylene, a very low density polyethylene, a linear low density polyethylene, a medium density polyethylene, a high density polyethylene, and a copolymer of ethylene and a vinyl compound of various kinds such as α-olefin having 3 to 12 carbon atoms, styrene, vinyl acetate, (meth)acrylate, (meth)acrylate ester and ionomer. The copolymer may be a random copolymer or a block copolymer and examples thereof include an α-olefin copolymer having 4 or more carbon atoms. In the present invention, the major component indicates a constituent component contained in the largest proportion as compared to the other constituent components contained, relatively. In the substrate layer 5, the amount of the polymer containing the above-described α-olefin is usually from about 50 to 100 weight % and preferably from about 70 to 100 weight %.

Furthermore, as a method of regulating the Young's modulus E′ of the substrate layer 5 in the range of 100 to 1,000 MPa, when an olefin polymer has the Young's modulus E′ of higher than 1,000 MPa, there is known a method of making a composite with a thermoplastic elastomer having the Young's modulus E′ of less than 100 MPa. As an alloy structure thereof, the alloy structure in which the olefin polymer forms a continuous phase and the thermoplastic elastomer forms a dispersed phase is preferable.

As the aforementioned thermoplastic elastomer, the same polymer as the one used for the adhesive layer (A) of the present invention can be used. When the substrate layer 5 consists of a plurality of layers of two or more, it is preferable that the Young's modulus E′ of the substrate layer 1 is in the range of 100 to 1,000 MPa, where the plural layers are considered as a single layer. It is possible to constitute the structure so as to allocate various properties required for an adhesive tape to each layer, respectively.

For example, in order to enhance the expanded peeling property, an intermediate layer of the substrate layer 5 is imparted an optimum Young's modulus E′, stretchability or tear resistance in processing, and weather resistance can be improved by adding a weather-resistant stabilizer thereto. The outermost layer of the substrate layer 5 can be exemplified by an embodiment, which is imparted resistance to surface scratches, sliding properties at the time of being expanded, and peeling properties from the adhesive layer (A) for ease of winding off the wound protecting film. The layers adjacent to each other may comprise any material as far as the layers can firmly adhere to each other by melt co-extruding.

Furthermore, an intermediate layer in the substrate layer 5 which is in contact with the adhesive layer (A) preferably contains a polymer comprising the above-described α-olefin, or a mixture of two or more kinds thereof as the major component, because the adhesive layer (A) and the intermediate layer constituting a part of the substrate layer 5 can strongly be integrated together. In the intermediate layer which is in contact with the adhesive layer (A), the content of the polymer comprising the above-described α-olefin is usually from about 50 to 100 weight % and preferably from about 70 to 100 weight %.

The surface layer, i.e., the outermost layer on the opposite side of the adhesive layer (A) attaching side of the substrate layer 5, preferably contains an ethylene polymer as the major component. Among such polymers, a low density polyethylene, a linear low density polyethylene, a medium density polyethylene, a high density polyethylene and an ethylene/(meth)acrylate copolymer are suitable. In this case, in the surface layer, i.e., the outermost layer of the substrate layer 5, the content of the ethylene copolymer is usually from about 50 to 100 weight % and preferably from about 70 to 100 weight %, and other α-olefin (co)polymers and the like may also be contained.

Furthermore, when the substrate layer 5 consists of an intermediate layer and a surface layer, the thickness of the intermediate layer is preferably from about 40 to 400 μm, while the thickness of the surface layer is preferably from about 5 to 50 μm.

The substrate layer 5 may contain a variety of additives which are generally used for such kind of substrate layer of an adhesive tape. For example, various fillers, pigments, UV absorbers, antioxidants, heat-resistant stabilizers, lubricants and the like may be contained to such an extent that the wafer, i.e., an adherend, is not adversely affected.

Next, a method of manufacturing the adhesive film of the present invention is described.

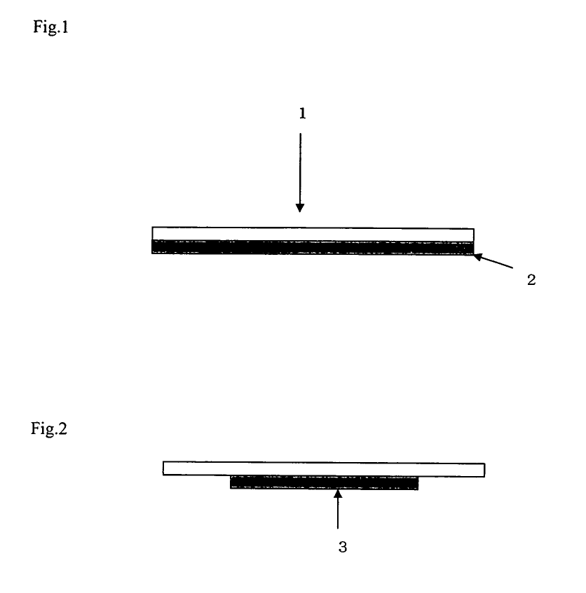

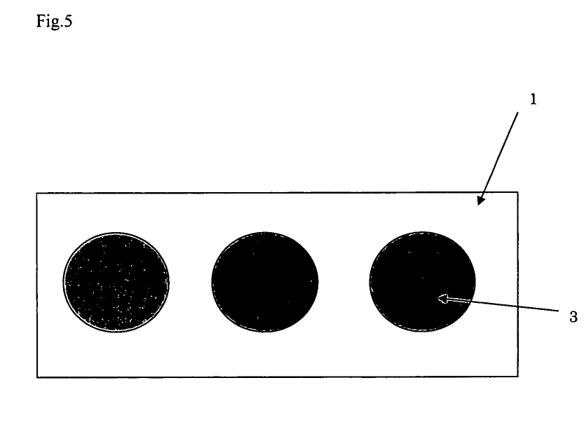

After a die attach film with release sheet (FIG. 1) is prepared by the foregoing methods, then the part corresponding to the die attach film is cut roundly in the shape of a silicon wafer by punching (FIG. 2). A dicing tape from which a release sheet is peeled off (FIG. 3) is laminated on the die attach film at a room temperature under atmospheric pressure, using a laminator, and thereby a die attach film functioning as a dicing sheet comprising a release film, a die attach film and a dicing tape (FIG. 4) is obtained. A top view of the dicing sheet function-fed die attach film is illustrated in FIG. 5.

A preferred embodiment of the film of the present invention comprises a release film, an adhesive layer (B), an adhesive layer (A) and a substrate. Examples of the release film used in the present invention include a polyethyleneterephthalate film, a polyethylene film, a polyethylene film, a polypropylene film, a polyester film, a polyimide film, a polyetherimide film, a polyether naphthalate film, a methylpentene film and the like. These films may be treated with a silicone release material, or a silica release material.

The total thickness of the thus formed adhesive layer is preferably from 3 to 100 μm and more preferably from 10 to 75 μm. When the thickness is less than 3 μm, the adhesive layer is less effective as an adhesive, while when the thickness exceeds 100 μm, the accuracy of the thickness becomes worse in some cases.

The adhesive film functioning as a dicing tape with a die attach film of the present invention is used in the same manner as a dicing tape in general, and it can be used by attaching a semiconductor chip to the die attach film part, particularly at the time of dicing. A temperature required for attaching is preferably about 100° C. After attaching the adhesive film to the back surface of the wafer, the wafer is fixed on a dicing machine, and a silicon semiconductor wafer attached with the adhesive film is cut into units of die using a cutting means such as a dicing saw to obtain semiconductor chips in the form of a die. Subsequently, with the adhesive layer (B) remaining stuck to the back surface of the semiconductor chip, only the dicing tape substrate (the adhesive layer (A) and the substrate) is peeled away using a pickup machine. At this time, any pickup apparatus usually used can be used. In this manner, a semiconductor chip attached with a die attach film can be obtained. Next, the semiconductor chip with the adhesive layer (B) fixed thereto can be die bonded to a metal lead frame or a substrate via the adhesive layer (B) by heating and pressing. The heating and pressing conditions are usually a heating temperature of from 100 to 300° C. and the time for pressing of 1 to 10 seconds, and preferably a heating temperature of from 100 to 200° C. and the time for pressing of 1 to 5 seconds. Subsequently, when a thermosetting adhesive component is contained in the adhesive layer (B), as a follow-up treatment, the thermosetting adhesive component in the adhesive layer (B) is cured by further heating, then a semiconductor device in which the semiconductor chip is firmly attached to the lead frame, the substrate or the like. In this case, the heating temperature is usually from about 100 to 300° C. and preferably from about 150 to 250° C., while the time for heating is usually from 1 to 240 minutes and preferably from 10 to 60 minutes.

The finally cured adhesive layer (B) has high heat resistance, and a resin component contained in the adhesive layer, having an imide ring which does not concern thermosetting, e.g. a cured product of the polyimide resin having high heat resistance, has low brittleness, excellent shear strength, high impact resistance, and heat resistance.

### EXAMPLES

The present invention is now more specifically illustrated with reference to Examples. However, the present invention is not limited to these Examples.

(Preparation Example of an Adhesive Layer (B))

### Synthesis Example

(I) Thermosetting Adhesive Component

(I-1) Epoxy Compound (VG3101, manufactured by Mitsui Chemicals, Inc.)

(I-2) Imidazole Type Hardener (2MAOK-PW, manufactured by Shikoku Chemicals Corporation)

(II) Silica Type Filler (1-FX, manufactured by Tatsumori Co.)

(III) Synthesis Example of Polyimide Resin Component

### Synthesis Example 1

17.00 g of 4,4′-bis(3-aminophenoxy)biphenyl, 40.14 g of polytetramethyleneoxide-di-p-aminobenzoate (product name: Elasmer 1000, average molecular weight: 1,305, manufactured by Ihara Chemical Industry Co., Ltd.), 86.37 g of N-methyl-2-pyrrolidone and 37.09 g of mesitylene were measured and put into a 300-ml, 5-necked separable flask provided with a stirrer, a nitrogen gas inlet tube, a thermometer and a Dienstag tube filled with mesitylene. The resulting mixture was heated at 50° C. under a nitrogen atmosphere to dissolve, then 25.05 g of oxy-4,4′-diphthalate dianhydride was added in small portions. Then, the nitrogen gas inlet tube was inserted into the solution (in a bubbling state), and the solution was heated so that the temperature in the system is from 170 to 180° C. and retained for 10 hours while performing azeotropic removal of water. After cooling, 61.67 g of N-methyl-2-pyrrolidone and 26.49 g of mesitylene were added for diluting to obtain a solution of a polyimide (III-1). The logarithmic viscosity number of the polyimide (III-1) measured using an Ubbelohde viscometer at 35° C. after dissolving in N-methyl-2-pyrrolidone to prepare a solution at a concentration of 0.5 g/dl was 0.45 dl/g.

### Synthesis Example 2

180 g of 1,3-bis(3-aminophenoxy)benzene, 17.06 g of 10Si (average molecular weight: 926, manufactured by Dow Corning Toray Co., Ltd.), 1038.16 g of N-methyl-2-pyrrolidone and 444.93 g of mesitylene were measured and put into a 3-L, 5-necked separable flask provided with a stirrer, a nitrogen gas inlet tube, a thermometer and a Dienstag tube filled with mesitylene. The resulting mixture was heated at 50° C. under a nitrogen atmosphere to dissolve, and 217.03 g of oxy-4,4′-diphthalate dianhydride and 95.6871 g of ethylene glycol bistrimellitate dianhydride (EGTA) (RKACID TMEG-1000, average molecular weight: 410.3, manufactured by New Japan Chemical Co., Ltd.) were added in small portions. Then, the nitrogen gas inlet tube was inserted into the solution (in a bubbling state), and the solution was heated so that the temperature in the system is from 170 to 180° C. and retained for 14 hours while performing azeotropic removal of water. After cooling, 42.77 g of 1,3-bis(3-aminophenoxy)benzene was subsequently added and diluted by adding 200.57 g of N-methyl-2-pyrrolidone and 266.89 g of mesitylene to obtain a solution of a polyimide (III-2). The logarithmic viscosity number of the polyimide (III-2) measured using an Ubbelohde viscometer at 35° C. after dissolving in N-methyl-2-pyrrolidone at a concentration of 0.5 g/dl was 0.24 dl/g.

(Preparation Example 1 of an Adhesive Layer (B))

Each component was mixed in the weight ratio described in Table 1, and the resulting mixture was fully mixed in a stirrer, to obtain an adhesive resin composition. The resin composition thus obtained was cast on a surface treated PET film (NK281 having a thickness of 50 μm, manufactured by Toyobo Co., Ltd.) to obtain a roll-shaped adhesive layer (B) (DAF-1) having a thickness of 25 μm. The DAF-1 thus obtained functions as a die attach film. The glass transition temperature (Tg) of the obtained adhesive layer (B) measured by a TMA (TMA4000, manufactured by Macscience Co., Ltd.) was 49° C.

(Preparation Example 2 of an Adhesive Layer (B))

A roll-shaped adhesive layer (B) (DAF-2) having a thickness of 25 μm was obtained in the same manner as in Preparation Example 1, except that the mixture ratio of an adhesive component was changed as shown in Table 1. The adhesive layer (B) thus obtained functions as a die attach film. The glass transition temperature (Tg) of the obtained adhesive layer (B) measured by a TMA (TMA4000, manufactured by Macscience Co., Ltd.) was 50° C.

(Preparation of an Adhesive Sheet Comprising the Adhesive Layer (A) and Substrate)

(Preparation Example 1 of an Adhesive Sheet comprising the Adhesive Layer (A) and Substrate DC-1)

A substrate layer comprising a surface layer and an intermediate layer was prepared in a laminated manner with the adhesive layer (A) according to a co-extrusion molding process. The substrate layer consists of two layers as the component constituting the surface layer of the substrate layer, 100 weight parts of a low density polyethylene (LDPE; density 0.92 g/cm³) was used. As the component constituting the intermediate layer of the substrate layer, 70 weight parts of a syndiotactic propylene polymer (s-PP; FINAPLAS™ 1571; density 0.87 g/cm³; manufactured by Atofina Petrochemicals, Inc.), 28 weight parts of an ethylene/butene copolymer (EB-A; density 0.87 g/cm³) and 2 weight parts of high density polyethylene (HDPE; density 0.96 g/cm³) were used. As the component constituting the adhesive layer (A), 72 weight parts of a propylene/1-butene/4-methyl-1-pentene copolymer (PB(4-MP); 43 mole % propylene component, 26 mole % 1-butene component, 31 mole % 4-methyl-1-pentene component), 8 weight parts of a propylene polymer (h-PP; density 0.91 g/cm³, 8 weight parts of an olefin (crystalline)/ethylene/butylene/olefin (crystalline) block copolymer (CEBC; DYNARON™ 6200P, manufactured by JSR Corporation), 8 weight parts of a styrene/isoprene/styrene block copolymer (SIS; SIS5229N, manufactured by JSR Corporation) and 4 weight parts of an ethylene/α-olefin cooligomer (LEO; Lucant™ HC-20, manufactured by Mitsui Chemicals, Inc.) were used.

Then, the material of each layer was melted in an extruder equipped with a full-flighted screw. Molding conditions (melting temperature) were 220° C. for the adhesive layer, 230° C. for the intermediate layer and 220° C. for the outer layer, and these molten resins for the 3 layers were laminated in a multi-layer die (co-extrusion temperature: 230° C.). The extruded adhesive sheet was cooled, slit and wound around a core material.

The tape (DC-1) consisting of two layers of a substrate layer and an adhesive layer was thus prepared, and the thickness of each layer was 15 μm for the adhesive layer, 75 μm for the intermediate layer and 10 μm for the outer layer, and the total thickness was 100 μm.

(Preparation Example 2 of an Adhesive Sheet comprising the Adhesive Layer (A) and Substrate DC-2)

The substrate layer was made of 2 layers. As the component constituting a surface layer of the substrate layer, 100 weight parts of LDPE used in Preparation Example 1 was used. As the component constituting an intermediate layer of the substrate layer, 60 weight parts of LDPE used in the surface layer, and 40 weight parts of EB-A used in Preparation Example 1 were used. As the component constituting the adhesive layer, 80 weight parts of PB(4-MP) used in Preparation Example 1, 10 weight parts of CEBC used in Preparation Example 1, 7 weight parts of SIS used in Preparation Example 1 and 3 weight parts of LEO used in Preparation Example 1 were used.

Then, the material of each layer was melted in an extruder equipped with a full-flighted screw.

Molding conditions (melting temperature) were 220° C. for the adhesive layer, 220° C. for the intermediate layer and 220° C. for the outer layer, and molten resins of the 3 layers were laminated in a multi-layer die (co-extrusion temperature: 220° C.). The extruded adhesive sheet was cooled, slit and wound around a core material. (DC-2)

The dicing tape thus obtained was a laminate of the substrate layer composed of two layers and the adhesive layer (A), and the thickness of each layer was 15 μm for the adhesive layer, 75 μm for the intermediate layer and 10 μm for the outer layer, and the total thickness was 100 μm.

### Example 1

A die attach film part of a film functioning as a die attach film previously prepared in combinations described in Table 1 (FIG. 1) was cut roundly in a shape of a silicon wafer by punching (FIG. 2). A release film of a previously prepared adhesive sheet comprising an adhesive layer (A) functioning as a dicing tape and a substrate was peeled away (FIG. 3). By laminating at room temperature under atmospheric pressure using a laminator (FIG. 4), an adhesive film comprising an adhesive layer (A) and a substrate functioning, which functions as a dicing tape with a die attach film, comprising a protecting film, a die attach film (adhesive layer (B)) and a dicing tape substrate (adhesive layer (A)+substrate layer), was obtained.

### Example 2

An adhesive film comprising an adhesive layer (A) and a substrate, which functions as a dicing tape with a die attach film was obtained in the same manner as in Example 1, except that the combination of the adhesive layers was changed as described in Table 2.

### Comparative Example 1

An adhesive film comprising an adhesive layer (A) and a substrate, which functions as a dicing tape with a die attach film, was obtained in the same manner as in Example 1, except that the combination of the adhesive layers was changed as described in Table 2.

(Evaluation of the Adhesive Film)

The adhesive films prepared in Examples and Comparative Example were evaluated in accordance with the following method.

(Evaluation Method)

(1) Adhesive Film having a Pressure Sensitive Adhesive Layer (A)

The protecting film of the adhesive film was peeled off, and then a back surface of a silicon wafer was attached on the adhesive layer (B) at 80° C. In attaching, attachment was carried out so as to be uniform by rolling using a manual roll. Next, the silicon wafer was fixed and set in a dicer, and cut in a chip size of 5×5 mm square using a dicing saw at a spindle speed of 25,000 rpm and at a cutting speed of 20 mm/sec for evaluating its capacity as a dicing sheet. Subsequently, a part of the dicing tape substrate (adhesive layer (A)+substrate) was peeled away from the semiconductor chip with the adhesive layer (B) remaining thereon using a pickup device (DE35i-6, manufactured by ROYCE Corporation) for evaluating the pickup property.

(2) Chip Flying in Dicing

After dicing a semiconductor wafer, the number of the semiconductor chips which were peeled away from the die attach film due to weakness of adhesion was measured for evaluation. The results were shown in Table 3.

(3) Chipping Property

O: Maximum width of chipping in chips of less-than 30 μm

X: Maximum width of chipping in chips of not less than 30 μm

The evaluation results were shown in Table 3.

(4) Pickup Property

After dicing the semiconductor wafer, whether the semiconductor chips attached with the die attach film could be picked up from the substrate or not was evaluated.

O: Almost all chips could be picked up

X: Not more than 50% of the chips could be picked up

The evaluation results were shown in Table 3.

(5) Peel Strength Measurement

For the measurement of the peel strength, a STROGRAPH-M1, manufactured by Toyo Seiki Seisaku-sho, LTD., was used.

An adhesive film was laminated on a silicon wafer at 80° C. and then the 180° peel strength of an adhesive layer (A) and an adhesive layer (B) was measured.

The evaluation results were shown in Table 3.

(6) Initial Adhesion as a Die Attach Film

In order to evaluate the heat resistance of an adhesive layer (B), the adhesive layer (B) cut in the shape of 5 mm square was put between a silicon chip of 5 mm square and a silicon chip of 20 mm square, and heat-pressed at 200° C. under load of 0.1 N for 1 second, then heat-cured at 180° C. under no load for 3 hours. The shear strength of the test chip thus obtained was measured during heating at 260° C. for 30 seconds using a share tester and evaluated. The results were shown in Table 3.

O: Shear Strength of not less than 2 MPa

X: Shear Strength of less than 2 MPa

### INDUSTRIAL APPLICABILITY

The adhesive film of the present invention functions as a dicing tape in a step of dicing and functions as a die bonding film which is superior in connection reliability in a step of bonding a semiconductor device and a supporting member. Additionally, in a step of attaching, the adhesive film can be attached to the wafer at low temperature, and a semiconductor device can be manufactured at low cost. Further, a process of manufacturing the semiconductor device can be simplified.

TABLE 1

| | (I) Thermosetting Adhesive | | | (III) Polyimide | |
|---|---|---|---|---|---|
| | Component | | | Resin Component | |
| | (I-1) | (I-2) | (II) Filler | (III-1) | (III-2) |
| Preparation | 20 | 1 | 15 | 100 | |
| Example (1) | | | | | |
| Preparation | 20 | 0.525 | 15 | | 100 |
| Example (2) | | | | | |

TABLE 2

| | Dicing Tape | Die Attach Film |
|---|---|---|
| | (Adhesive Layer A) | (Adhesive Layer B) |
| Example 1 | DC1 | DAF1 |
| Example 2 | DC1 | DAF2 |
| Comparative | DC2 | DAF1 |
| Example 1 | | |

TABLE 3

| | Dicing Tape | | | |
|---|---|---|---|---|
| | Number of | | | |
| | chip flying | Pickup | Chipping | Die Attach Film |
| | after dicing | property | property | Initial adhesion |
| Example 1 | None | ∘ | ∘ | ∘ |
| Example 2 | None | ∘ | ∘ | ∘ |
| Comparative | None | x | ∘ | — |
| Example 1 | | | | |

TABLE 4

| | | Peel Strength (N/10 mm) |
|---|---|---|
| | | Adhesive layer (A)/ |
| | Peeling Interface | Adhesive layer (B) |
| Example 1 | Adhesive layer (B)/ | 0.4 |
| | Adhesive layer (A) | |
| Example 2 | Adhesive layer (B)/ | 0.4 |
| | Adhesive layer (A) | |
| Comparative | Adhesive layer (B)/ | 0.8 |
| Example 1 | Si | |

1. An adhesive film comprising a layer in which an adhesive layer (A) comprising an olefin polymer and an adhesive layer (B) are adjacently laminated to each other, wherein the 180° peel strength between the layer (A) and the layer (B) is 0.7 N/10 mm or less.

2. The adhesive film according to claim 1, wherein the layer (B) comprises a polyimide resin.

3. The adhesive film according to claim 2, wherein the glass transition temperature (Tg) of the layer (B) is 50° C. or less.

4. The adhesive film according to claim 1, wherein the layer (A) comprises one, or two or more kinds of copolymer including at least two kinds of α-olefin selected from α-olefins having 2 to 12 carbon atoms as the major unit components.

5. The adhesive film according to claim 2, wherein the layer (B) further comprises a thermosetting resin.

6. The adhesive film according to claim 1, wherein the layer (B) comprises 0 to 70 volume % of a filler.

7. The adhesive film according to claim 1, wherein the layer (B) is laminated onto a part of the surface of the layer (A).

8. A method of manufacturing a semiconductor device, comprising a step of cutting a semiconductor wafer into chips after attaching the adhesive film according to claim 1 to the semiconductor wafer via the layer (B), a step of peeling off the layer (A) from the layer (B) at the interface thereof to give chips attached with the layer (B), and a step of attaching the chips having the layer (B) thereon to a substrate having circuits thereon, or a film having circuits thereon, via the layer (B).

9. The method of manufacturing a semiconductor device according to claim 8, wherein a temperature for laminating the layer (B) onto a semiconductor wafer is 100° C. or less.

10. A semiconductor device manufactured by the method according to claim 8.

11. A semiconductor device manufactured by the method according to claim 9.
